(19) United States
(12) Patent Application Publication
(10) Pub. No.: US 2010/0257415 A1
(43) Pub. Date: Oct. 7, 2010

(54) INSTRUCTION-BASED PROGRAMMABLE MEMORY BUILT-IN SELF TEST CIRCUIT AND ADDRESS GENERATOR THEREOF

(75) Inventors: Chung-Fu Lin, Taipei County (TW); Yeong-Jar Chang, Taichung County (TW)

Correspondence Address: J C PATENTS, 4 VENTURE, SUITE 250, IRVINE, CA, 92618, US

(73) Assignee: FARADAY TECHNOLOGY CORP., Hsinchu (TW)

(21) Appl. No.: 12/416,646

(22) Filed: Apr. 1, 2009

(51) Int. Cl. G11C 29/12; G06F 11/22; G06F 12/02

(52) U.S. Cl. 714/718; 711/200; 714/E11.145; 711/E12.002

(57) ABSTRACT

An instruction-based programmable memory built-in self test (P-MBIST) circuit and an address generator thereof are provided. The P-MBIST circuit generates control signals according to the decoding of compact test instructions provided by an external automatic test equipment (ATE). The address generator generates memory addresses according to the control signals. The control signals and the memory addresses are sent to an embedded memory to perform the MBIST. The algorithm-specific design of the P-MBIST circuit and the address generator enables them to support multiple test algorithms at full clock speed and occupy smaller chip area.

### BACKGROUND OF THE INVENTION

1. Field of the Invention

The present invention relates to memory built-in self test (MBIST). More particularly, the present invention relates to an instruction-based programmable memory built-in self test (P-MBIST) circuit, its compact instruction format, its state controller design, and its address generator.

2. Description of the Related Art

Based on the defined memory fault model, the memory test can be viewed as a series of operations in terms of reading, writing, and comparing the output data and the expected data. For a memory array embedded in an integrated circuit (IC), the test procedure can be implemented in the chip so that the chip can test the embedded memory by itself, which is called memory built-in self-test (MBIST). In general, MBIST can be classified into three main types: hardwired MBIST, microcode-based programmable MBIST (P-MBIST), and instruction-based P-MBIST.

The hardwired MBIST is suitable for the implementation of specific test algorithms. This is because the controller is dedicated to the selected test algorithms. However, this design lacks the flexibility to accommodate any modification of test algorithms (i.e. no programmability).

The microcode-based P-MBIST defines the instruction format to support the operations of selected memory test algorithms. Its customized processor or controller is developed to execute the loaded instructions. In general, it uses a program memory to store the test program, and new test patterns can be added through modifying the test program during the test phase. Compared to the hardwired MBIST, the microcode-based P-MBIST provides higher programmability, but the designs of decoder, data path and controller become more complex. Besides, the instruction storage is an area-consuming component.

The instruction-based P-MBIST is based on a register bank with a capacity of a single instruction, which is proposed to eliminate the need of the program storage. Due to the capacity reduction of program storage, each test algorithm is decomposed into several sequences and each sequence is sequentially scanned into the register bank. Besides, the complexity of decoder is lowered due to the simplified loop control of program counter. However, instruction-based P-MBIST increases the effort of developers of test programs because more scan-in cycles are required to communicate with the external test programs. The extra effort is required only in the development stage, though. When the test program is debugged and finalized, instruction-based P-MBIST is as convenient as hardwired MBIST and microcode-based P-MBIST are. In terms of complexity and programmability, instruction-based P-MBIST is a compromise between hardwired MBIST and microcode-based P-MBIST.

### SUMMARY OF THE INVENTION

Accordingly, the present invention is directed to an instruction-based P-MBIST circuit and a two-level address generator of the instruction-based P-MBIST circuit. Due to a compact instruction format and the specialized two-level address generator, the instruction-based P-MBIST circuit features low complexity, small area, and supports multiple test algorithms.

According to an embodiment of the present invention, an instruction-based P-MBIST circuit and the address generator thereof are provided. The instruction-based P-MBIST circuit includes an instruction decoder, a state controller, an address generator, and a data comparator. The instruction decoder decodes a test instruction which includes a memory operation. The state controller generates a control signal according to the output of the instruction decoder. The address generator generates a memory address according to the control signal. The control signal and the memory address are provided to an embedded memory for performing the memory operation on the embedded memory. The data comparator compares the expected results of the memory operation with the actual results output by the embedded memory in response to the memory operation and outputs an error report if the expected results and the actual results do not match.

The address generator includes a first address calculator, a base row loop latch, and a base column loop latch. The first address calculator adds a first predetermined value or a second predetermined value to a base address according to the control signal. The aforementioned memory address is equal to the base address or is generated according to the base address. The base address includes a base row address and a base column address. The first address calculator determines a carry propagation order of the bits of the base address in the aforementioned adding according to the control signal. The base row loop latch stores and provides the base row address output by the first address calculator or the base row address output by the base row loop latch itself to the first address calculator according to the control signal. The base column loop latch stores and provides the base column address output by the first address calculator or the base column address output by the base column loop latch itself to the first address calculator according to the control signal.

The instruction-based P-MBIST circuit may further include an instruction reader and a clock switcher. The instruction reader receives the test instruction from an automatic test equipment (ATE) and providing the test instruction to the instruction decoder. The clock switcher is coupled to the instruction reader, the state controller, and the data comparator for providing synchronization between the external clock signal provided by the ATE and the internal clock signal of the instruction-based P-MBIST circuit.

The first address calculator may include a permuter, a first accumulator, and an inverse permuter. The permuter performs a permutation on the bits of the base address to enforce the carry propagation order according to the control signal. The first accumulator adds the first predetermined value or the second predetermined value to the output of the permuter according to the control signal. The inverse permuter performs an inverse permutation on the bits of the output of the first accumulator according to the control signal. The permutation and the inverse permutation are exactly inverse to each other.

The permuter may include a first rotation device, a second rotation device, and a switch device. The inverse permuter may include an inverse switch device, a first inverse rotation device, and a second inverse rotation device. The first rotation device performs a first rotation operation on the base row address according to a base row rotation signal. The second rotation device performs a second rotation operation on the base column address according to a base column rotation signal. The switch device exchanges bit orders of the output of the first rotation device and the output of the second rotation device in response to a switch signal. The switch device also provides the result of the exchanging to the first accumulator. The control signal includes the base row rotation signal, the base column rotation signal, and the switch signal. The inverse switch device exchanges bit orders of the row part and the column part of the output of the first accumulator in response to the switch signal. The first inverse rotation device performs a first inverse rotation operation on the row part of the output of the inverse switch device according to the base row rotation signal and then provides the result of the first inverse rotation operation to the base row loop latch. The first rotation operation and the first inverse rotation operation are opposite in direction. The second inverse rotation device performs a second inverse rotation operation on the column part of the output of the inverse switch device according to the base column rotation signal and then provides the result of the second inverse rotation operation to the base column loop latch. The second rotation operation and the second inverse rotation operation are opposite in direction.

The address generator may further include a second address calculator, a local row loop latch, a row multiplexer, a third address calculator, a local column loop latch, and a column multiplexer. The second address calculator adds a third predetermined value or a fourth predetermined value to the base row address or a local row address according to the control signal, and then provides the result of the adding as the local row address. In addition, the second address calculator determines the carry propagation order of the bits of the local row address in the aforementioned adding according to the control signal. The local row loop latch stores and provides the local row address output by the second address calculator or the local row address output by the local row loop latch itself to the second address calculator according to the control signal. The row multiplexer outputs the base row address output by the base row loop latch or the local row address output by the local row loop latch as the row address of the memory address according to the control signal. The third address calculator, the local column loop latch, and the column multiplexer are counterparts of the second address calculator, the local row loop latch, and the row multiplexer. The difference is that the third address calculator, the local column loop latch, and the column multiplexer manipulate the base column address and the local column address instead of the base row address and the local row address. For brevity, their discussions are omitted here.

The second address calculator may include a third rotation device, a second accumulator, and a third inverse rotation device. The third rotation device outputs the base row address provided by the base row loop latch or performing a third rotation operation on the local row address provided by the local row loop latch according to a local row rotation signal. The second accumulator adds the third predetermined value or the fourth predetermined value to the output of the third rotation device according to a local row step signal. The third inverse rotation device performs a third inverse rotation operation on the output of the second accumulator according to the local row rotation signal, and then provides the result of the third inverse rotation operation as the local row address to the local row loop latch. The third rotation operation and the third inverse rotation operation are opposite in direction. The control signal includes the local row rotation signal and the local row step signal.

The test instruction includes an enable field and the enable field includes several enable bits. When all of the enable bits of the enable field are de-asserted, the state controller performs the memory operation on the embedded memory according to a basic march-like test algorithm. When one of the enable bits of the enable field is asserted, the state controller performs the memory operation on the embedded memory according to a complex test algorithm corresponding to the asserted enable bit. The march-like test algorithm and the complex test algorithms corresponding to the enable bits are all different. The enable bits integrate complex algorithms into the compact march-based test instruction format. The test program can execute a complex test algorithm by asserting a single enable bit in the test instruction, while the test instruction is still concise and compact.

The aforementioned compact instruction reduces design effort and cost of the state controller of the P-MBIST circuit. The state controller implements a finite state machine including a plurality of states. One of the states is corresponding to the memory operation of the test instruction. When all of the enable bits of the enable field are de-asserted, the corresponding state performs the memory operation on the embedded memory according to the march-like test algorithm. When one of the enable bits of the enable field is asserted, the corresponding state performs the memory operation on the embedded memory according to the complex test algorithm corresponding to the asserted enable bit. The basic march-like algorithm and the complex algorithm share the same state, which simplifies the design of the state controller.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram showing an instruction-based P-MBIST circuit according to an embodiment of the present invention.

FIG. 2A and FIG. 2B are block diagrams of the address generator in FIG. 1.

FIG. 3A to FIG. 3D are schematic diagrams showing the carry propagation orders of the conventional march-like test algorithm and the XMOVI and the YMOVI test algorithms supported by the instruction-based P-MBIST circuit in FIG. 1.

FIG. 4 is a schematic diagram describing the Butterfly test algorithm supported by the instruction-based P-MBIST circuit in FIG. 1.

FIG. 5 is a flow chart of the Row Disturb test algorithm supported by the instruction-based P-MBIST circuit in FIG. 1.

FIG. 6 is a schematic diagram showing the operation flow of some states of the finite state machine of the state controller of an instruction-based P-MBIST circuit according to another embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

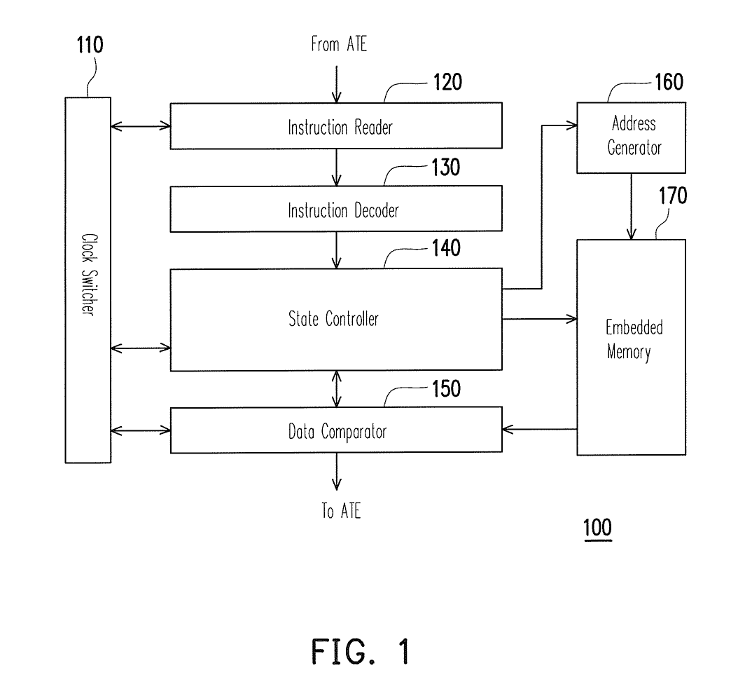

FIG. 1 is a block diagram showing an instruction-based P-MBIST circuit 100 according to an embodiment of the present invention. The circuit 100 includes the instruction reader 120, the instruction decoder 130, the state controller 140, the data comparator 150, the address generator 160, and the clock switcher 110. The circuit 100 and the embedded memory 170 are fabricated on the same chip. The circuit 100 performs MBIST on the embedded memory 170. The embedded memory 170 may be a dynamic random access memory (DRAM) or a static random access memory (SRAM). In this embodiment, the embedded memory 170 is a DRAM.

The P-MBIST circuit 100 is instruction-based and receives test instructions from an external ATE (not shown). The instruction reader 120 is a register bank with simple control logics. Each test instruction from the ATE is serially shifted into the instruction reader 120, and then the instruction reader 120 provides the test instruction to the instruction decoder 130. The instruction decoder 130 decodes the test instruction. The test instruction may include one or more user-defined memory operations. The state controller 140 generates a control signal according to the output of the instruction decoder 130. In fact, the control signal is a collection including many signals for controlling the address generator 160 and the embedded memory 170 (details later). The address generator 160 generates memory addresses for the user-defined memory operations according to the control signal. The control signal and the memory addresses are provided to the embedded memory 170 for performing the memory operations on the embedded memory 170. The data comparator 150 compares the expected result of the memory operations with the actual result output by the embedded memory 170 in response to the memory operations. If the expected result and the actual result do not match, the data comparator 150 outputs an error report to the ATE for further diagnosis process. The clock switcher 110 is coupled to the instruction reader 120, the state controller 140, and the data comparator 150 for providing synchronization between two different clock domains, namely, the external clock signal provided by the ATE and the internal clock signal of the instruction-based P-MBIST circuit 100.

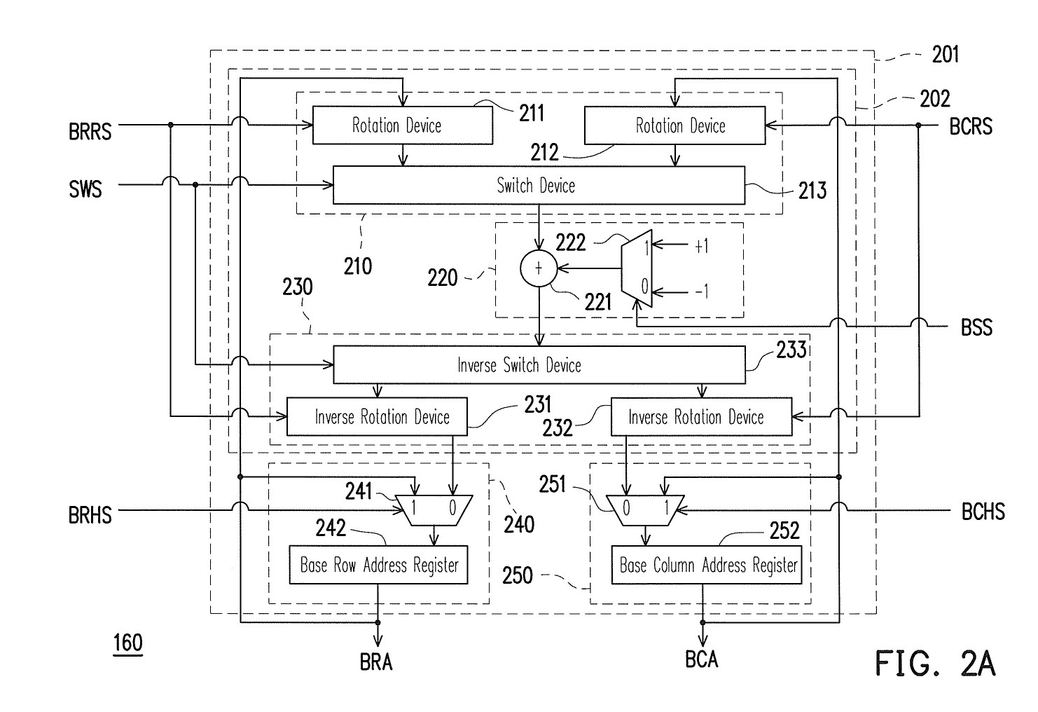

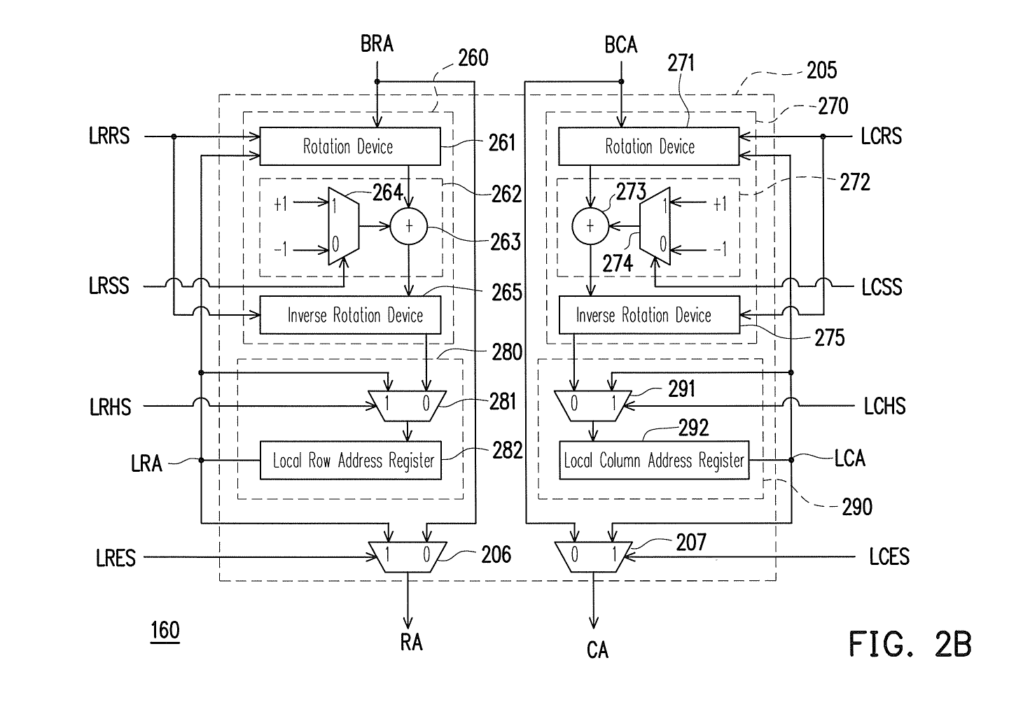

The address generator 160 features a two-level design and is a feature of this embodiment. FIG. 2A and FIG. 2B are detailed block diagrams of the address generator 160. The aforementioned two levels are the base address generator 201 in FIG. 2A and the local address generator 205 in FIG. 2B included in the address generator 160. The base address generator 201 generates a base address according to the control signal. The local address generator 205 generates a local address according to the control signal and the base address. One of the base address and the local address is selected and provided as the aforementioned memory address to the embedded memory 170. The test algorithm currently executed by the P-MBIST circuit 100 determines which address is selected as the memory address. The memory address consists of the row address RA and the column address CA. The local address consists of the local row address LRA and the local column address LCA. The base address consists of the base row address BRA and the base column address BCA.

The components of the address generator 160 are all controlled by the control signal provided by the state controller 140. Please refer to FIG. 2A and FIG. 2B. The control signal includes the base row rotation signal BRRS, the base column rotation signal BCRS, the switch signal SWS, the base step signal BSS, the base row hold signal BRHS, the base column hold signal BCHS, the local row rotation signal LRRS, the local column rotation signal LCRS, the local row step signal LRSS, the local column step signal LCSS, the local row hold signal LRHS, the local column hold signal LCHS, the local row enable signal LRES, and the local column enable signal LCES. These signals will be discussed in details later.

The base address generator 201 includes the address calculator 202, the base row loop latch 240, and the base column loop latch 250. The address calculator 202 adds a first predetermined value or a second predetermined value to the base address according to the base step signal BSS. This adding mechanism is used to let the base address step upward or step downward when the P-MBIST circuit 100 is executing test algorithms. In addition, the address calculator 202 determines the carry propagation order of bits of the base address according to the base row rotation signal BRRS, the base column rotation signal BCRS, and the switch signal SWS when one of the predetermined values is added to the base address. The determination of the carry propagation order is for some complex test algorithms supported by the P-MBIST circuit 100. More details will be given later.

The base row loop latch 240 stores the base row address BRA output by the address calculator 202 or the base row address BRA output by the base row loop latch 240 itself according to the base row hold signal BRHS and then provides the stored base row address BRA to the address calculator 202. In other words, the base row loop latch 240 provides the latest base row address BRA generated by the address calculator 202 or provides the last base row address BRA stored in itself according to the base row hold signal BRHS. Similarly, the base column loop latch 250 stores the base column address BCA output by the address calculator 202 or the base column address BCA output by the base column loop latch 250 itself according to the base column hold signal BCHS and then provides the stored base column address BCA to the address calculator 202. In other words, the base column loop latch 250 provides the latest base column address BCA generated by the address calculator 202 or provides the last base column address BCA stored in itself according to the base column hold signal BCHS.

The address calculator 202 includes the permuter 210, the accumulator 220, and the inverse permuter 230. The permuter 210 performs a permutation on the bits of the base address to enforce the carry propagation order according to the base row rotation signal BRRS, the base column rotation signal BCRS, and the switch signal SWS. The accumulator 220 adds the first predetermined value or the second predetermined value to the output of the permuter 210 according to the base step signal BSS. The inverse permuter 230 performs an inverse permutation on the bits of the output of the accumulator 220 according to the base row rotation signal BRRS, the base column rotation signal BCRS, and the switch signal SWS. The permutation performed by the permuter 210 and the inverse permutation performed by the inverse permuter 230 are exactly inverse to each other. In other words, they cancel each other.

The permuter 210 includes the rotation devices 211, 212, and the switch device 213. The rotation device 211 performs a first rotation operation on the base row address BRA provided by the base row loop latch 240. The degree of the first rotation operation is determined by the base row rotation signal BRRS. When the base row rotation signal BRRS indicates that rotation is unnecessary, the rotation device 211 outputs the base row address BRA directly without rotation.

The rotation device 212 performs a second rotation operation on the base column address BCA provided by the base column loop latch 250. The degree of the second rotation operation is determined by the base column rotation signal BCRS. When the base column rotation signal BCRS indicates that rotation is unnecessary, the rotation device 212 outputs the base column address BCA directly without rotation.

When the switch signal SWS is de-asserted, the switch device 213 just combines the output of the rotations devices 211 and 212, and then provides the combined address to the accumulator 220. When the switch signal SWS is asserted, the switch device 213 exchanges the bit orders of the output of the rotation devices 211 and 212, and then provides the result of the exchanging to the accumulator 220.

The accumulator 220 includes the adder 221 and the multiplexer 222. When the base step signal BSS is asserted, the multiplexer 222 outputs the first predetermined value. When the base step signal BSS is de-asserted, the multiplexer 222 outputs the second predetermined value. In this embodiment, the first predetermined value is +1, which let the base address step upward. The second predetermined value is −1, which let the base address step downward. The adder 221 adds the output of the multiplexer 222 to the output of the permuter 210 and provides the result of the adding to the inverse permuter 230.

The inverse permuter 230 includes the inverse switch device 233 and the inverse rotation devices 231 and 232. When the switch signal SWS is de-asserted, the inverse switch device 233 just outputs the output of the accumulator 220. When the switch signal SWS is asserted, the inverse switch device 233 exchanges the bit orders of the row part and the column part of the output of the accumulator 220.

The inverse rotation device 231 performs a first inverse rotation operation on the row part of the output of the inverse switch device 233. The degree of the first inverse rotation operation is determined by the base row rotation signal BRRS. The first rotation operation performed by the rotation device 211 and the first inverse rotation operation performed by the inverse rotation device 231 are opposite in direction. In other words, they cancel each other. When the base row rotation signal BRRS indicates that rotation is unnecessary, the inverse rotation device 231 outputs the row part of the output of the inverse switch device 233 directly without rotation. The output of the inverse rotation device 231 is provided to the base row loop latch 240 as the latest base row address BRA.

The inverse rotation device 232 performs a second inverse rotation operation on the column part of the output of the inverse switch device 233. The degree of the second inverse rotation operation is determined by the base column rotation signal BCRS. The second rotation operation performed by the rotation device 212 and the second inverse rotation operation performed by the inverse rotation device 232 are opposite in direction. In other words, they cancel each other. When the base row rotation signal BRRS indicates that rotation is unnecessary, the inverse rotation device 232 outputs the column part of the output of the inverse switch device 233 directly without rotation. The output of the inverse rotation device 232 is provided to the base column loop latch 250 as the latest base column address BCA.

The permuter 210 rearranges the order of the bits of the base address. The accumulator 220 adds one of the two predetermined values to the permuted base address. In the adding, the carry is propagated from the permuted least significant bit (LSB) to the permuted most significant bit (MSB), which is the propagation order expected by the user. The inverse permuter 230 restores the order of the bits of the base address. In this way, the permuter 210 and the inverse permuter 230 enforce the carry propagation order of the base address.

The base row loop latch 240 includes the multiplexer 241 and the base row address register 242. The base row address register 242 stores and provides the base row address BRA to the address calculator 202 and the local address generator 205. When the base row hold signal BRHS is asserted, the multiplexer 241 outputs the base row address BRA output by the base row address register 242 to the base row address register 242. In this case, the last base row address BRA is repeated again. When the base row hold signal BRHS is de-asserted, the multiplexer 241 outputs the base row address output by the address calculator 202 to the base row address register 242. In this case, the latest base row address generated by the address calculator 202 is stored and provided.

The base column loop latch 250 includes the multiplexer 251 and the base column address register 252. The base column address register 252 stores and provides the base column address BCA to the address calculator 202 and the local address generator 205. When the base column hold signal BCHS is asserted, the multiplexer 251 outputs the base column address BCA output by the base column address register 252 to the base column address register 252. In this case, the last base column address BCA is repeated again. When the base column hold signal BCHS is de-asserted, the multiplexer 251 outputs the base column address output by the address calculator 202 to the base column address register 252. In this case, the latest base column address generated by the address calculator 202 is stored and provided.

The local address generator 205 includes the address calculators 260 and 270, the local row loop latch 280, the local column loop latch 290, the row multiplexer 206, and the column multiplexer 207.

The address calculator 260 adds a third predetermined value or a fourth predetermined value to the base row address BRA or the local row address LRA according to the local row rotation signal LRRS and the local row step signal LRSS. The address calculator 260 provides the result of the adding as the local row address LRA. Moreover, the address calculator 260 determines the carry propagation order of the bits of the local row address LRA in the aforementioned adding according to the local row rotation signal LRRS.

The local row loop latch 280 stores and provides the local row address LRA output by the address calculator 260 or the local row address LRA output by the local row loop latch 280 itself to the address calculator 260 according to the local row hold signal LRHS.

When the local row enable signal LRES is de-asserted, the row multiplexer 206 outputs the base row address BRA output by the base row loop latch 240 as the row address RA of the memory address used to test the embedded memory 170. When the local row enable signal LRES is asserted, the row multiplexer 206 outputs the local row address LRA output by the local row loop latch 280 as the row address RA of the aforementioned memory address.

The address calculator 260 includes the rotation device 261, the accumulator 262, and the inverse rotation device 265. When the local row rotation signal LRRS is de-asserted, the rotation device 261 simply outputs the base row address BRA provided by the base row loop latch 240. When the local row rotation signal LRRS is asserted, the rotation device 261 performs a third rotation operation on the local row address LRA provided by the local row loop latch 280.

The accumulator 262 adds the third predetermined value or the fourth predetermined value to the output of the rotation device 261 according to the local row step signal LRSS.

When the local row rotation signal LRRS is de-asserted, the inverse rotation device 265 simply receives and outputs the output of the accumulator 262 as the local row address LRA to the local row loop latch 280. When the local row rotation signal LRRS is asserted, the inverse rotation device 265 performs a third inverse rotation operation on the output of the accumulator 262, and then provides the result of the third inverse rotation operation as the local row address LRA to the local row loop latch 280. The third rotation operation and the third inverse rotation operation are opposite in direction and cancel each other. In this embodiment, the third rotation operation is a 1-bit right rotation and the third inverse rotation operation is a 1-bit left rotation.

The accumulator 262 includes the adder 263 and the multiplexer 264. When the local row step signal LRSS is asserted, the multiplexer 264 outputs the third predetermined value. When the local row step signal LRSS is de-asserted, the multiplexer 264 outputs the fourth predetermined value. In this embodiment, the third predetermined value is +1, which let the local row address step upward. The fourth predetermined value is −1, which let the local row address step downward. The adder 263 adds the output of the multiplexer 264 to the output of the rotation device 261 and provides the result of the adding to the inverse rotation device 265.

When the local row rotation signal LRRS is asserted, the rotation device 261 rearranges the order of the bits of the local row address LRA. The accumulator 262 adds one of the two predetermined values to the permuted local row address. In the adding, the carry is propagated from the permuted LSB to the permuted MSB, which is the propagation order expected by the user. The inverse rotation device 265 restores the order of the bits of the local row address LRA. In this way, the rotation device 261 and the inverse rotation device 265 enforce the carry propagation order of the local row address LRA.

The local row loop latch 280 includes the multiplexer 281 and the local row address register 282. The local row address register 282 stores and provides the local row address LRA to the row multiplexer 206, the multiplexer 281, and the address calculator 260. When the local row hold signal LRHS is asserted, the multiplexer 281 outputs the local row address LRA output by the local row address register 282 to the local row address register 282. In this case, the last local row address LRA is repeated again. When the local row hold signal LRHS is de-asserted, the multiplexer 281 outputs the local row address output by the address calculator 260 to the local row address register 282. In this case, the latest local row address generated by the address calculator 260 is stored and provided.

The address calculator 270 adds a fifth predetermined value or a sixth predetermined value to the base column address BCA or the local column address LCA according to the local column rotation signal LCRS and the local column step signal LCSS. The address calculator 270 provides the result of the adding as the local column address LCA. Moreover, the address calculator 270 determines the carry propagation order of the bits of the local column address LCA in the aforementioned adding according to the local column rotation signal LCRS.

The local column loop latch 290 stores and provides the local column address LCA output by the address calculator 270 or the local column address LCA output by the local column loop latch 290 itself to the address calculator 270 according to the local column hold signal LCHS.

When the local column enable signal LCES is de-asserted, the column multiplexer 207 outputs the base column address BCA output by the base column loop latch 250 as the column address CA of the memory address used to test the embedded memory 170. When the local column enable signal LCES is asserted, the column multiplexer 207 outputs the local column address LCA output by the local column loop latch 290 as the column address CA of the aforementioned memory address.

The address calculator 270 includes the rotation device 271, the accumulator 272, and the inverse rotation device 275. When the local column rotation signal LCRS is de-asserted, the rotation device 271 simply outputs the base column address BCA provided by the base column loop latch 250. When the local column rotation signal LCRS is asserted, the rotation device 271 performs a fourth rotation operation on the local column address LCA provided by the local column loop latch 290.

The accumulator 272 adds the fifth predetermined value or the sixth predetermined value to the output of the rotation device 271 according to the local column step signal LCSS.

When the local column rotation signal LCRS is de-asserted, the inverse rotation device 275 simply receives and outputs the output of the accumulator 272 as the local column address LCA to the local column loop latch 290. When the local column rotation signal LCRS is asserted, the inverse rotation device 275 performs a fourth inverse rotation operation on the output of the accumulator 272, and then provides the result of the fourth inverse rotation operation as the local column address LCA to the local column loop latch 290. The fourth rotation operation and the fourth inverse rotation operation are opposite in direction and cancel each other. In this embodiment, the fourth rotation operation is a 1-bit right rotation and the fourth inverse rotation operation is a 1-bit left rotation.

The accumulator 272 includes the adder 273 and the multiplexer 274. When the local column step signal LCSS is asserted, the multiplexer 274 outputs the fifth predetermined value. When the local column step signal LCSS is de-asserted, the multiplexer 274 outputs the sixth predetermined value. In this embodiment, the fifth predetermined value is +1, which let the local column address step upward. The sixth predetermined value is −1, which let the local column address step downward. The adder 273 adds the output of the multiplexer 274 to the output of the rotation device 271 and provides the result of the adding to the inverse rotation device 275.

When the local column rotation signal LCRS is asserted, the rotation device 271 rearranges the order of the bits of the local column address LCA. The accumulator 272 adds one of the two predetermined values to the permuted local column address. In the adding, the carry is propagated from the permuted LSB to the permuted MSB, which is the propagation order expected by the user. The inverse rotation device 275 restores the order of the bits of the local column address LCA. In this way, the rotation device 271 and the inverse rotation device 275 enforce the carry propagation order of the local column address LCA.

The local column loop latch 290 includes the multiplexer 291 and the local column address register 292. The local column address register 292 stores and provides the local column address LCA to the column multiplexer 207, the multiplexer 291, and the address calculator 270. When the local column hold signal LCHS is asserted, the multiplexer 291 outputs the local column address LCA output by the local column address register 292 to the local column address register 292. In this case, the last local column address LCA is repeated again. When the local column hold signal LCHS is de-asserted, the multiplexer 291 outputs the local column address output by the address calculator 270 to the local column address register 292. In this case, the latest local column address generated by the address calculator 270 is stored and provided.

Table 1 lists the fields of the test instruction in this embodiment and the descriptions of the fields.

TABLE 1
Fields of the Test Instruction

| Field Name | Description |
|---|---|
| UP/DN | Up/down address counting/stepping direction |
| Repeat | Enabling or disabling test algorithms including XMOVI and |
| | YMOVI |
| Enable | Enabling or disabling test algorithms including Hammer |
| | Read, Hammer Write, Refresh, Data Retention, Butterfly, |
| | Row Disturb, and Column Disturb |
| Retention | Specifying the length of the idle time of the Data Retention |
| | test algorithm |
| Operation | Specifying the details of the read/write operations of the test |
| | algorithms |

The fields Repeat, Enable, and Retention are used to support more complex test algorithms including Hammer Read, Hammer Write, Refresh, Data Retention, XMOVI, YMOVI, Butterfly, Row Disturb, and Column Disturb. The remaining UP/DN field and Operation field may be used to support basic march-like test algorithms. A conventional march-like algorithm includes one or many march elements. Each march element is represented by a test instruction. A march element includes one or many memory read/write operations. These memory operations are specified in the Operation field of the test instruction corresponding to the march element. The UP/DN field specifies whether the memory address is stepping upward or downward in the march element.

In this embodiment, the Operation field may specify up to four memory operations and each memory operation is specified by three 1-bit subfields. Table 2 lists the subfields of the Operation field of the test instruction and their descriptions. Obviously, the Operation field includes twelve subfields in total, namely, the three subfields of the first memory operation followed by the three subfields of the second, third, and fourth memory operations, respectively.

TABLE 2
Subfields of the Operation Field of the Test Instruction

| Subfield Name | Description |
|---|---|
| EOC (end | The value 0 means the current memory operation is the |
| of command) | last in the current test instruction and there is no need to |
| | check the subfields of the following memory operations. |
| | The value 1 means the current memory operation is not |
| | the last and the subfields of the next memory operation |
| | have to be checked. |
| W/R | The value 1 means the current memory operation is a |
| | read operation. The value 0 means the current memory |
| | operation is a write operation. |
| Polarity | The data to be written into the embedded memory or the |
| | expected data to be read from the embedded memory (1 |
| | or 0) |

In a conventional march-like test algorithm, the memory address is counted upward or downward and several read/write memory operations are performed at each memory address. The aforementioned UP/DN field and Operation field are sufficient to support conventional march-like test algorithms.

The 2-level address generator 160 includes the base address generator 201 and the local address generator 205. The base address generator 201 generates memory addresses for the conventional march-like test algorithms and the test algorithms Hammer Read, Hammer Write, XMOVI, and YMOVI. The local address generator 205 generates memory addresses for the test algorithms Butterfly, Row Disturb, and Column Disturb. The support of the test algorithms Refresh and Data Retention is the cooperation of the state controller 140 and the address generator 160.

For conventional march-like test algorithms, the Repeat field and the Enable field of the test instruction are all zero (de-asserted). In this case, the state controller 140 de-asserts the base row rotation signal BRRS, the base column rotation signal BCRS, and the switch signal SWS. Consequently, the permuter 210 does not perform the permutation and the inverse permuter 230 does not perform the inverse permutation. The base row address BRA stored in the base row address register 242 and the base column address BCA stored in the base column address register 252 are combined by the permuter 210 as the base address and transmitted to the accumulator 220 directly without bit order rearrangement. The state controller 140 generates the base step signal BSS according to the UP/DN field of the test instruction. The accumulator 220 adds +1 or −1 to the base address according to the base step signal BSS to generate the next base address. Next, the inverse permuter 230 divides the new base address into a new base row address and a new base column address. The state controller 140 de-asserts the base row hold signal BRHS and the base column hold signal BCHS according to the Enable field. In response, the multiplexer 241 directs the new base row address to the base row address register 242 and the multiplexer 251 directs the new base column address to the base column address register 252. The state controller 140 also de-asserts the local row enable signal LRES and the local column enable signal LCES according to the Enable field. In response, the row multiplexer 206 outputs the new base row address BRA as the row address RA and the column multiplexer 207 outputs the new base column address BCA as the column address CA. The row address RA and the column address CA are merged as the memory address, which is sent to the embedded memory 170 to perform the read/write memory operations.

The user may turn on or turn off more complex test algorithms by toggling the bits of the Enable field and the Repeat field. For example, if a Refresh Enable Bit in the Enable field is one (asserted), the P-MBIST circuit 100 executes the Refresh test algorithm. If a Butterfly Enable Bit in the Enable field is one (asserted), the P-MBIST circuit 100 executes the Butterfly test algorithm. If all bits of the Enable field and the Repeat field are zero (de-asserted), the P-MBIST circuit 100 executes the conventional march-like test algorithm. Since the more complex test algorithms are enabled or disabled according to only a few bits in the test instruction, the test instruction is in a compact format without the need of complex addressing fields of conventional test instructions. The state controller 140 implements a finite state machine to control the flow of the test algorithms. The various test algorithms share states of the finite state machine of the state controller 140. The various test algorithms also share the components of the address generator 160. The aforementioned design concepts not only shorten the test instruction, but also reduce the chip area of the P-MBIST circuit 100. Discussions regarding how the P-MBIST circuit 100 supports the more complex test algorithms are given below.

Table 3 shows the operations of an exemplary test instruction of a conventional march-like test algorithm and the variations of the operations in response to the assertion of several Enable Bits of the Enable field. The term “up(r0,w0,r0)” represents the operations of the march-like algorithm. The leading “up” means the memory address is stepping upward. The test instruction includes three operations represented by the three terms “r0”, “w0”, “r0” between the parentheses, respectively. The first “r0” means the first operation is a memory read operation and the expected result is zero. The term “w0” means the second operation is a memory write operation and the data to be written is zero. The second “r0” means the third operation is a memory read operation and the expected result is zero.

### Table 3, Comparison Among a March-Like Test Algorithm and Some Complex Test

TABLE 3
Comparison among a March-like Test Algorithm and Some
Complex Test Algorithms

| | Corresponding | |
|---|---|---|
| Test Algorithm | Enable Bit | Operations |
| March-like | None | up(r0, w0, r0) |
| Hammer Read and | Hammer Enable | up(r0, 10*w0, r0) |
| Hammer Write | | |
| Refresh | Refresh Enable | up(r0, w0, r0), and then |
| | | refresh for 2000 cycles |
| Data Retention | Retention Enable | up(r0, w0, r0), and then |
| | | delay for 10000 cycles |
| Butterfly | Butterfly Enable | up(r0, [symbol] (w0), r0) |

When all of the Enable Bits of the Enable field are zero (de-asserted), the state controller 140 controls the address generator 160 and the embedded memory 170 to perform the memory operations on the embedded memory 170 according to the conventional march-like test algorithm. The conventional march-like test algorithm performs each memory operation only once on memory cells of the embedded memory 170 corresponding to the base address. When one of the Enable Bits of the Enable field is one (asserted), the state controller 140 varies the memory operations according to the complex test algorithm corresponding to the asserted Enable Bit and controls the address generator 160 and the embedded memory 170 to perform the varied memory operations on the embedded memory 170. The variations of the operations in response to the assertion of the Enable Bits are discussed below.

The Hammer Read and the Hammer Write test algorithms differ from the conventional march-like algorithm in that a predetermined memory operation in the test instruction is repeated for a predetermined number of times. The Hammer Read test algorithm repeats a predetermined read operation, while the Hammer Write test algorithm repeats a predetermined write operation. In the example of Table 3, the Hammer Write algorithm repeats the “w0” operation for ten times, while the two “r0” operations are still performed only once. The flow and the repeating of the Hammer algorithms are controlled by the state controller 140. During the repeating, the address generator 160 simply provides the same memory address.

The Hammer Read and the Hammer Write algorithms may be enabled or disabled according to individual corresponding Enable Bits in the Enable field of the test instruction. Alternatively, as shown in Table 3, the Hammer Read and the Hammer Write algorithms may share a single Hammer Enable Bit in the Enable field. In this case, the state controller 140 may differentiate them by the number of memory operations in the test instruction. Which operation gets the repeating may be specified in the test instruction or built-in in the state controller 140. The predetermined number of times of the repeating may also be specified in the test instruction or built-in in the state controller 140.

The Refresh test algorithm is for DRAM only. The Refresh test algorithm differs from the conventional march-like algorithm in that the Refresh algorithm has the embedded DRAM refreshed for a predetermined number of cycles after each of some predetermined march elements. In the example of Table 3, the Refresh algorithm performs the three memory operations of the current march element and then sends refresh signals to the embedded DRAM to refresh the DRAM for two thousand cycles. The Refresh test algorithm may be enabled by a corresponding Refresh Enable Bit in the Enable field. When executing the Refresh test algorithm, the state controller 140 sends refresh signals to the embedded memory 170 to enforce the DRAM refresh cycles. The predetermined number of the refresh cycles may be specified in the test instruction or built-in in the state controller 140. Also, the number of refresh cycles may be programmable during the testing process.

The Data Retention test algorithm differs from the conventional march-like algorithm in that the Data Retention algorithm delays for a predetermined time duration after each of some predetermined march elements. In the example of Table 3, the Data Retention algorithm performs the three memory operations of the current march element and then idles for ten thousand clock cycles before performing the memory operations of the next march element. The Data Retention test algorithm may be enabled by a corresponding Retention Enable Bit in the Enable field. When executing the Data Retention test algorithm, the state controller 140 performs a countdown for each predetermined delay. During the countdown, the P-MBIST circuit 100 is idle and does nothing. The time length of the countdown, namely, the length of the predetermined delay, is specified in the Retention field of the test instruction. In other embodiments of the present invention, the length of the predetermined delay may be built-in in the state controller 140. Also, the length of the delay may be programmable during the testing process.

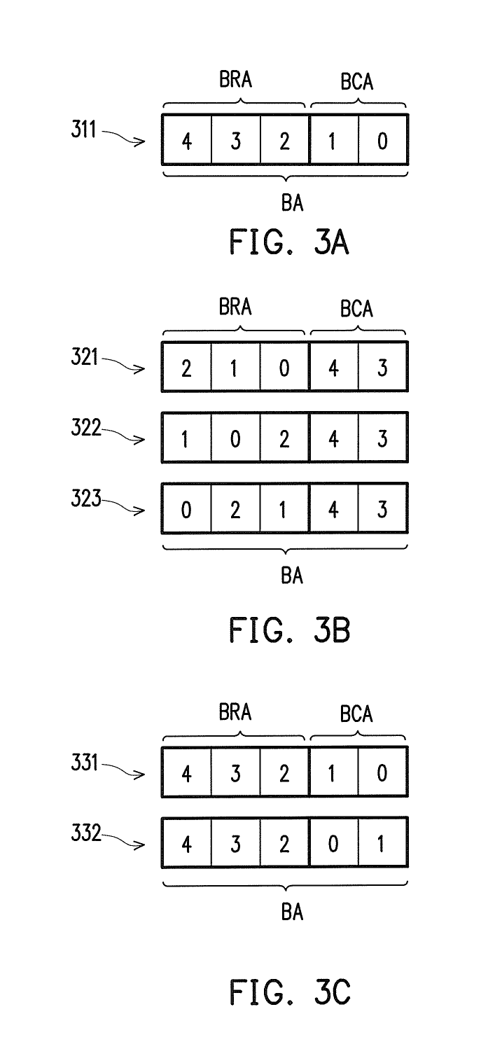

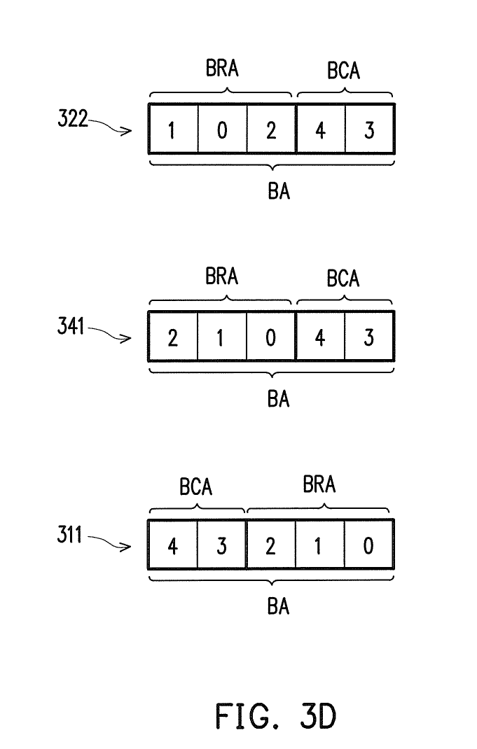

The XMOVI and YMOVI test algorithms differ from conventional march-like algorithms in their carry propagation orders. Please refer to FIG. 3A, FIG. 3B, and FIG. 3C, which shows the carry propagation orders of the conventional march-like test algorithms, the XMOVI test algorithm, and the YMOVI test algorithm, respectively, for an example of 5-bit base addresses. The 5-bit base address BA consists of the 3-bit base row address BRA and the 2-bit base column address BCA. In each carry propagation order shown in FIG. 3A-3C, the predetermined step value (+1 for example) is added to the bit labeled “0”. The carry of the addition of the bit labeled “0” is added to the bit labeled “1”. The carry of the addition of the bit labeled “1” is added to the bit labeled “2”. The carry of the addition of the bit labeled “2” is added to the bit labeled “3”. The carry of the addition of the bit labeled “3” is added to the bit labeled “4”.

FIG. 3A shows the normal carry propagation order 311 of conventional march-like test algorithms, wherein the carry propagation order is from the LSB to the MSB of the base address BA. The XMOVI test algorithm uses the carry propagation order 321 first, and then uses the carry propagation order 322, and then uses the carry propagation order 323. The YMOVI test algorithm uses the carry propagation order 331 first, and then uses the carry propagation order 332. For example, Table 4 lists a base address sequence of the carry propagation order 322 of the XMOVI test algorithm.

The carry propagation orders in FIG. 3B and FIG. 3C involve switching and rotation of the base row address BRA and the base column address BCA. The permuter 210 and the inverse permuter 230 enforce the special carry propagation orders of the XMOVI and the YMOVI test algorithms. The state controller 140 generates the base row rotation signal BRRS, the base column rotation signal BCRS, and the switch signal SWS according to the Repeat field of the test instruction in order to control the permuter 210 and the inverse permuter 230.

TABLE 4
Comparison of the Normal Carry Propagation Order and
an Exemplary XMOVI Carry Propagation Order

| The normal | The XMOVI |
|---|---|
| order 311 | order 322 |
| 000_00 | 000_00 |
| 000_01 | 010_00 |
| 000_10 | 100_00 |
| 000_11 | 110_00 |
| 001_00 | 001_00 |
| 001_01 | 011_00 |
| 001_10 | 101_00 |
| 001_11 | 111_00 |
| 010_00 | 000_01 |
| 010_01 | 010_01 |
| 010_10 | 100_01 |
| 010_11 | 110_01 |
| 011_00 | 001_01 |
| 011_01 | 011_01 |
| 011_10 | 101_01 |
| 011_11 | 111_01 |
| 100_00 | 000_10 |

For example, FIG. 3D shows the process of enforcing the carry propagation order 322 of the XMOVI test algorithm. First, the permuter 210 receives the base address BA. The rotation device 211 changes the carry propagation order 322 to the carry propagation order 341 by performing the first rotation operation on the base row address BRA according to the base row rotation signal BRRS. In the example of FIG. 3D, the first rotation operation may be a 1-bit right rotation or a 2-bit left rotation. Next, the switch device 213 changes the carry propagation order 341 to the normal carry propagation order 311 by exchanging the bit orders of the base row address BRA and the base column address BCA according to the switch signal SWS. The accumulator 220 performs an addition on the base address BA according to the normal carry propagation order 311. The inverse switch device 233 changes the normal carry propagation order 311 to the carry propagation order 341 by exchanging the bit orders of the base row address BRA and the base column address BCA according to the switch signal SWS. Next, the inverse rotation device 231 changes the carry propagation order 341 to the carry propagation order 322 by performing the first inverse rotation operation on the base row address BRA according to the base row rotation signal BRRS. If the first rotation operation is a 1-bit right rotation, the first inverse rotation operation is a 1-bit left rotation. If the first rotation operation is a 2-bit left rotation, the first inverse rotation operation is a 2-bit right rotation.

Take the carry propagation order 332 of the YMOVI test algorithm as another example. In order to enforce the carry propagation order 332, the rotation device 212 rotates the base column address BCA according to the base column rotation signal BCRS. The state controller 140 de-asserts the switch signal SWS according to the Repeat field of the test instruction. In response, the switch device 213 and the inverse switch device 233 do not perform the switching. After the accumulator 220 performs the addition on the base address BA, the inverse rotation device 232 restores the base column address BCA according to the base column rotation signal BCRS.

The Repeat field of the test instruction enables or disables the XMOVI and the YMOVI test algorithms. In this embodiment, the Repeat field consists of two bits, namely, Repeat_X and Repeat_Y. Table 5 lists the combinations and descriptions of Repeat_X and Repeat_Y.

When (Repeat_X, Repeat_Y) is equal to (0, 0), both XMOVI and YMOVI are disabled. The address calculator 202 enforces the carry propagation order 311 of conventional march-like test algorithms. When (Repeat_X, Repeat_Y) is equal to (1, 0) for the first time, XMOVI is enabled and the address calculator 202 enforces the carry propagation order 321. When (Repeat_X, Repeat_Y) is equal to (1, 0) for the second time, XMOVI is enabled and the address calculator 202 enforces the carry propagation order 322. When (Repeat_X, Repeat_Y) is equal to (1, 0) for the third time, XMOVI is enabled and the address calculator 202 enforces the carry propagation order 323. When (Repeat_X, Repeat_Y) is equal to (0, 1), YMOVI is enabled and the address calculator 202 enforces the carry propagation order 332. When (Repeat_X, Repeat_Y) is equal to (1, 1), the state controller 140 maintains the current carry propagation order. That is, the current test instruction uses the carry propagation order of the previous test instruction.

TABLE 5
Values and Descriptions of the Repeat Field of the Test Instruction

| (Repeat_X, | |
|---|---|
| Repeat_Y) | Description |
| (0, 0) | Disabling XMOVI and YMOVI |
| (1, 0) | Enabling XMOVI |
| (0, 1) | Enabling YMOVI |
| (1, 1) | Holding the current carry |
| | propagation order |

The state controller 140 generates the base row rotation signal BRRS, the base column rotation signal BCRS, and the switch signal SWS according to the aforementioned combinations of Repeat_X and Repeat_Y. The permuter 210 and the inverse permuter 230 enforce the carry propagation orders in the aforementioned manner according to the signals BRRS, BCRS and SWS. Since the Repeat field occupies only two bits in the test instruction, the Repeat field is very compact and helps to simplify the design of the P-MBIST circuit 100.

The memory address sequences of the test algorithms above are generated by the base address generator 201. The memory address sequences of the following test algorithms Butterfly, Row Disturb, and Column Disturb are generated by the local address generator 205.

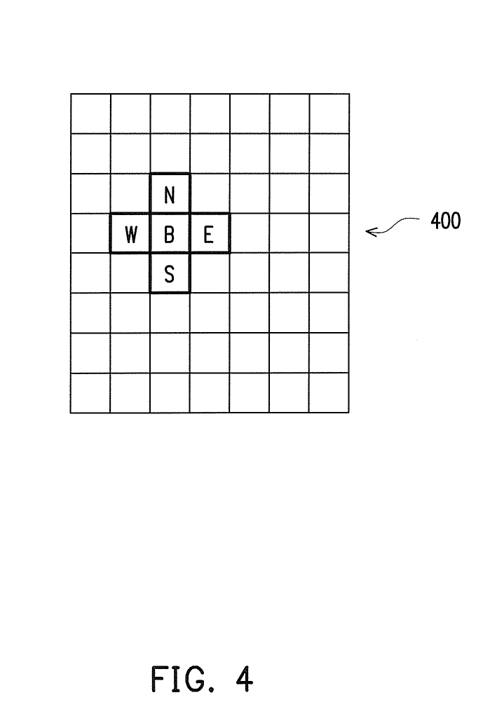

The Butterfly test algorithm checks each memory cell of the embedded memory 170 several times. When checking a memory cell, the Butterfly test algorithm reads the current memory cell and expects a predetermined value, and then writes another predetermined value into the four memory cells adjacent to the current memory cell, and then reads the current memory cell again to examine whether there is any cross interference between the current cell and the adjacent cells. In the example of Table 3, the Butterfly algorithm performs the first operation “r0” on the current memory cell, and then performs the second operation “w0” on the four memory cells adjacent to the current memory cell, and then performs the third operation “r0” on the current memory cell. The symbol [symbol] means the four memory cells adjacent to the current memory cell. Therefore, the address generator 160 provides the memory address of the current memory cell and then provides the memory addresses of the four adjacent cells. For example, please refer to FIG. 4, which illustrates an exemplary memory cell array 400. There are five memory cells labelled “B”, “N”, “E”, “S”, and “W” respectively in the cell array 400. According to this example, the “B” cell is the current memory cell. The address generator 160 provides the memory addresses of the five memory cells in the order “B”, “N”, “E”, “S”, and “W”.

The Butterfly test algorithm is enabled by a Butterfly Enable Bit in the Enable field of the test instruction. When the Butterfly algorithm is enabled, the state controller 140 asserts and de-asserts the related signals accordingly. When the Butterfly algorithm passes through the memory cells, the base address generator 201 generates a conventional march-like address sequence. The memory address of the “B” cell is the base address provided by the base address generator 201 and the memory addresses of the adjacent cells are the local addresses provided by the local address generator 205.

When the Butterfly test algorithm checks the “B” cell in FIG. 4, the base address generator 201 provides the memory address of the “B” cell. The state controller 140 de-asserts the local row enable signal LRES and the local column enable signal LCES. In response, the row multiplexer 206 outputs the base row address BRA as the row address RA and the column multiplexer 207 outputs the base column address BCA as the column address CA.

Later, when the Butterfly test algorithm writes into the four adjacent cells, the state controller 140 asserts the base row hold signal BRHS and the base column hold signal BCHS so that the base address generator 201 keeps outputting the memory address of the “B” cell. The state controller 140 also de-asserts the local row rotation signal LRRS and the local column rotation signal LCRS so that the carry propagation order of the local address is unchanged. The state controller 140 also de-asserts the local row hold signal LRHS and the local column hold signal LCHS so that the local row loop latch 280 and the local column loop latch 290 output the latest local address.

When the Butterfly test algorithm writes into the “N” cell, the state controller 140 de-asserts the local row step signal LRSS, asserts the local row enable signal LRES, and de-asserts the local column enable signal LCES so that the address generator 160 outputs the row address of the “N” cell and the column address of the “B” cell, which is also the column address of the “N” cell.

When the Butterfly test algorithm writes into the “E” cell, the state controller 140 asserts the local column step signal LCSS, asserts the local column enable signal LCES, and de-asserts the local row enable signal LRES so that the address generator 160 outputs the column address of the “E” cell and the row address of the “B” cell, which is also the row address of the “E” cell.

When the Butterfly test algorithm writes into the “S” cell, the state controller 140 asserts the local row step signal LRSS, asserts the local row enable signal LRES, and de-asserts the local column enable signal LCES so that the address generator 160 outputs the row address of the “S” cell and the column address of the “B” cell, which is also the column address of the “S” cell.

When the Butterfly test algorithm writes into the “W” cell, the state controller 140 de-asserts the local column step signal LCSS, asserts the local column enable signal LCES, and de-asserts the local row enable signal LRES so that the address generator 160 outputs the column address of the “W” cell and the row address of the “B” cell, which is also the row address of the “W” cell.

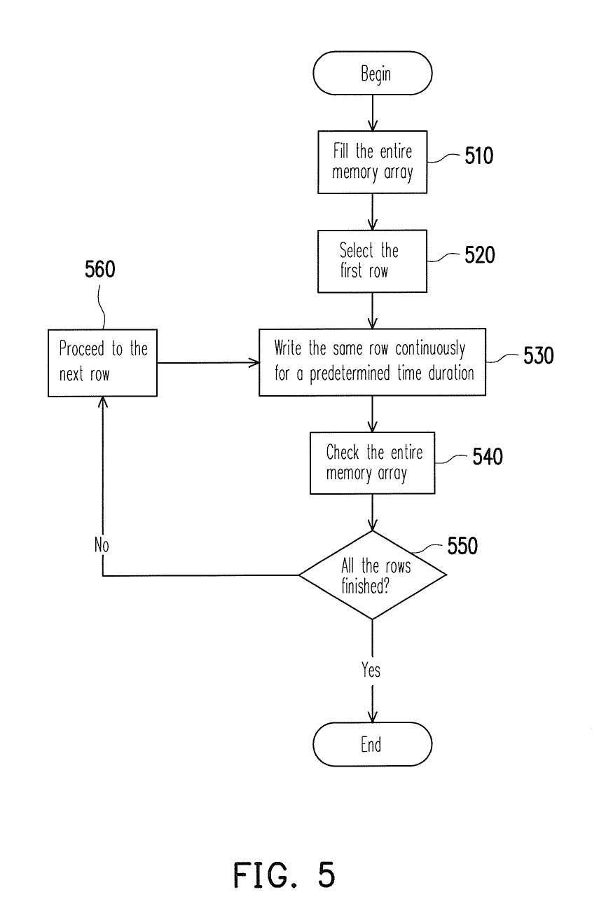

FIG. 5 is a flow chart of the Row Disturb test algorithm supported by the P-MBIST circuit 100. First, fill each memory cell of the embedded memory 170 with a predetermined value (0 or 1) (step 510). Select the first row (step 520). Write the predetermined value into the selected row continuously for a predetermined time duration (2 milliseconds for example) (step 530). In step 530, the predetermined value is written into the first memory cell of the selected row, and then written into the second memory cell of the selected row, and so on, until the predetermined value is written into the last memory cell of the selected row. Next, the writing of the predetermined value starts from the first memory cell of the selected row all over again, until the predetermined time duration expires.

After the expiration of the predetermined time duration, read each memory cell of the embedded memory 170 and check whether each memory cell retains the predetermined value or not (step 540). Next, check whether all the rows of the embedded memory 170 are tested or not (step 550). If there are any untested rows left, the Row Disturb test algorithm selects the next row (step 560), and then the flow returns to step 530. The flow stops if all the rows are tested.

The Row Disturb test algorithm tests the even rows first, and then test the odd rows. Take an 8-row memory array as example. The Row Disturb test algorithm would test the rows according to the row address sequence 0, 2, 4, 6, 1, 3, 5, 7. The address calculator 260 can generates this row address sequence under the control of the state controller 140.

The Row Disturb test algorithm is enabled by a corresponding Enable Bit in the Enable field of the test instruction. When the Row Disturb algorithm is enabled and proceeds to step 530, the state controller 140 asserts the local row hold signal LRHS and the local row enable signal LRES so that the address generator 160 keeps outputting the row address of the selected row. In addition, the state controller 140 controls the base address generator 201 to count the base column address BCA and de-asserts the local column enable signal LCES so that the address generator 160 outputs the base column address BCA as the column address CA. In this way, the memory addresses sent to the embedded memory 170 move along the same selected row during the predetermined time duration. The predetermined time duration may be specified in the test instruction or built-in in the state controller 140.

When the Row Disturb algorithm finishes the selected row and proceeds to the next row (step 560), the state controller 140 asserts the local row rotation signal LRRS accordingly so that the rotation device 261 and the inverse rotation device 265 change the carry propagation order of the local row address LRA. When the local row rotation signal LRRS is asserted, the rotation device 261 performs a 1-bit right rotation on the local row address LRA and the inverse rotation device 265 performs a 1-bit left rotation on the local row address LRA. The state controller 140 also asserts the local row step signal LRSS so that the accumulator 262 adds +1 to the rotated local row address LRA at every clock cycle. As a result, the local row address LRA counts the even rows and then counts the odd rows. The state controller 140 also de-asserts the local row hold signal LRHS so that the row address of the next selected row enters the local row address register 282.

The Column Disturb test algorithm is similar to the Row Disturb test algorithm. The difference is that the Column Disturb test algorithm writes the predetermined value into each memory cell column continuously for the predetermined time duration instead of writing into each memory cell row. When the Column Disturb test algorithm is enabled, the state controller 140 controls the address calculator 270, the local column loop latch 290, and the column multiplexer 207 in the same way as the state controller 140 controls the address calculator 260, the local row loop latch 280, and the row multiplexer 206 during the Row Disturb test algorithm.

In this embodiment, the Enable field of the test instruction includes several Enable Bits. Each Enable Bit is used to enable or disable a corresponding test algorithm. In other words, the Enable field selects the test algorithm executed by the P-MBIST circuit 100. When every bit of the Enable field is zero, the P-MBIST circuit 100 executes the conventional march-like algorithm. In some other embodiments of the present invention, the Enable field may be implemented in another form. In this case, the entire Enable field is decoded as a single integer and each valid value of this integer represents a test algorithm supported by the P-MBIST circuit 100. For example, the P-MBIST circuit 100 may executes the XMOVI test algorithm when the value of the Enable field is five and executes the Butterfly test algorithm when the value of the Enable field is seven. The test instruction may be more compact according to the alternative scheme.

The Enable field of the test instruction integrates complex test algorithms into the compact march-based instruction format. The test program can execute any of the aforementioned complex algorithms by simply asserting an Enable Bit or setting the Enable field to a corresponding integer, while the test instruction is still concise and compact. This compact instruction format enables the P-MBIST circuit to support multiple complex test algorithms and simultaneously reduces design effort and cost of the P-MBIST circuit.

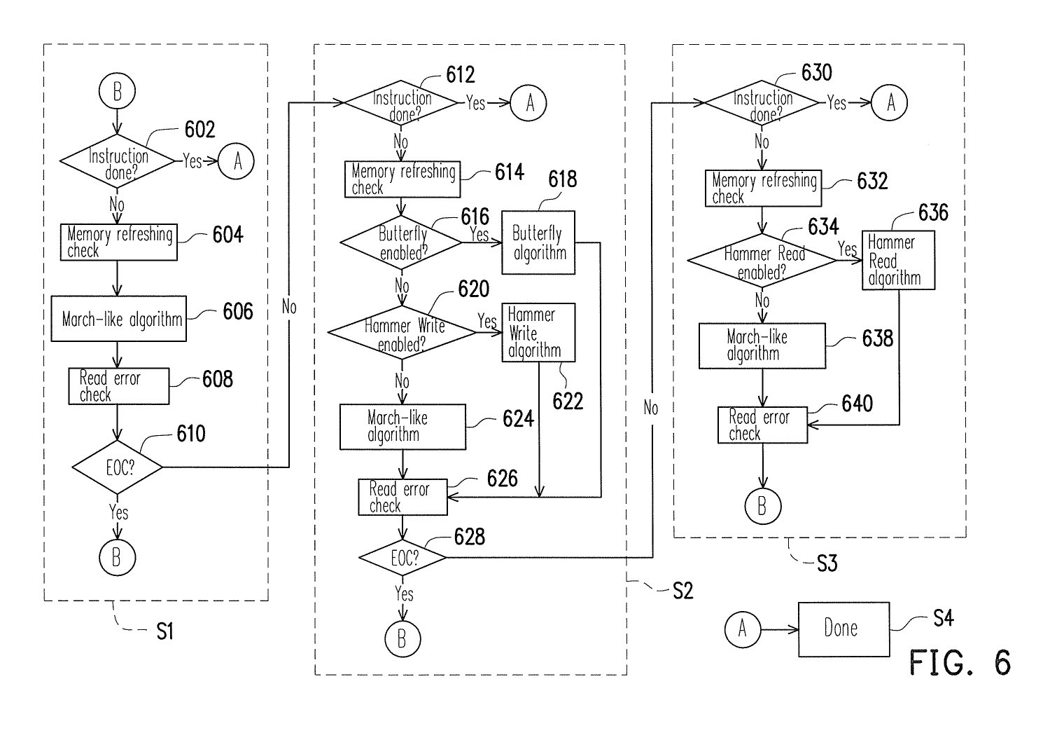

For example, the design of the state controller of the P-MBIST circuit can be simplified by the compact instruction format. FIG. 6 is a schematic diagram showing the operation flow of four states S1-S4 of the finite state machine implemented by the state controller of an instruction-based P-MBIST circuit according to an embodiment of the present invention. In this embodiment, a test instruction includes three memory operations at most and the three memory operations are performed by the states S1-S3, respectively. The state S4 is corresponding to the completion of the test instruction. The complex test algorithms do not vary the first memory operation of the test instruction. The second memory operation may be varied by the Butterfly or the Hammer Write test algorithm. The third memory operation may be varied by the Hammer Read test algorithm.

Each of the states S1-S3 includes many conditional checks. The first check of the state S1 is checking whether the memory address of the test instruction finishes counting or not (step 602). If the memory address finishes counting, the test instruction is done and the flow proceeds to the state S4. If the counting is not finished yet, the test instruction continues and the flow proceeds to the second check. If the embedded memory is a DRAM, it needs periodical refreshing. The second check is checking whether the refreshing time of the embedded DRAM is due (step 604). If the refreshing time is due, the state S1 sends a refresh signal to the embedded DRAM.

Next, the state S1 performs the first memory operation of the test instruction on the embedded memory according to a conventional march-like test algorithm (step 606). If the first memory operation is a read operation and the actual result read from the embedded memory is different from the expect result of the first memory operation, an error report is provided to the ATE (step 608).

Next, the state S1 checks the EOC subfield of the first memory operation (step 610). If the first memory operation is the last operation of the test instruction, the flow returns to the first step of the first state S1 in order to execute the test instruction all over again at the next memory address. Otherwise, the flow proceeds to the first step of the next state (step 612 of S2) in order to perform the next memory operation of the test instruction.

The steps 612, 614, 626 and 628 of the state S2 are similar to the steps 602, 604, 608 and 610 of the state S1, respectively. Therefore, their discussions are omitted for brevity. The state S2 checks whether the Butterfly Enable Bit is asserted or not (step 616). If the Butterfly Enable Bit is asserted, the state S2 performs the second memory operation of the test instruction on memory cells adjacent to the current memory cells of the embedded memory according to the Butterfly test algorithm (step 618). If the Butterfly Enable Bit is de-asserted, the state S2 checks whether the Hammer Write Enable Bit is asserted or not (step 620). If the Hammer Write Enable Bit is asserted, the second memory operation has to be a write operation and the state S2 repeats the write operation on the embedded memory according to the Hammer Write test algorithm (step 622). If all the Enable Bits of the Enable field are de-asserted, the state S2 performs the second memory operation on the embedded memory according to the conventional march-like test algorithm (step 624).

The steps 630, 632 and 640 of the state S3 are similar to the steps 602, 604 and 608 of the state S1, respectively. Therefore, their discussions are omitted for brevity. The state S3 checks whether the Hammer Read Enable Bit is asserted or not (step 634). If the Hammer Read Enable Bit is asserted, the third memory operation has to be a read operation and the state S3 repeats the read operation on the embedded memory according to the Hammer Read test algorithm (step 636). If all the Enable Bits of the Enable field are de-asserted, the state S3 performs the third memory operation on the embedded memory according to the conventional march-like test algorithm (step 638).

The state S2 differs from the state S1 in steps 616-622 which are corresponding to the complex test algorithms. The Butterfly and the Hammer Write test algorithms share the state S2 with the conventional march-like test algorithm. The state S2 executes one of the three algorithms according to the Enable Bits of the Enable field. Similarly, the Hammer Read test algorithm shares the state S3 with the conventional march-like test algorithm. The state S3 executes one of the two algorithms according to the Enable Bits of the Enable field. Due to the compact format of the test instruction, the states of the finite state machine can be shared to simply the design of the state controller.

In summary, the P-MBIST circuit provided by the present invention features a compact test instruction format and a two-level address generator. Due to simplified test instruction and hardware sharing, the P-MBIST circuit and the address generator can support multiple complex test algorithms with low hardware complexity and small chip area. Furthermore, the P-MBIST circuit can be easily incorporated into a memory compiler or the design flow of an application-specific integrated circuit (ASIC).

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An instruction-based programmable memory built-in self test (P-MBIST) circuit, comprising:
an instruction decoder for decoding a test instruction comprising a memory operation;
a state controller for generating a control signal according to an output of the instruction decoder;
an address generator for generating a memory address according to the control signal, wherein the control signal and the memory address are provided to an embedded memory for performing the memory operation on the embedded memory; and
a data comparator for comparing an expected result of the memory operation with an actual result output by the embedded memory in response to the memory operation and outputting an error report if the expected result and the actual result do not match;
wherein the address generator comprises:
a first address calculator for adding a first predetermined value or a second predetermined value to a base address according to the control signal, wherein the memory address is equal to the base address or is generated according to the base address, the base address comprises a base row address and a base column address, and the first address calculator determines a carry propagation order of bits of the base address in the adding according to the control signal;
a base row loop latch for storing and providing the base row address output by the first address calculator or the base row address output by the base row loop latch to the first address calculator according to the control signal; and
a base column loop latch for storing and providing the base column address output by the first address calculator or the base column address output by the base column loop latch to the first address calculator according to the control signal.

2. The instruction-based P-MBIST circuit of claim 1, further comprising:
an instruction reader for receiving the test instruction from an automatic test equipment and providing the test instruction to the instruction decoder; and
a clock switcher coupled to the instruction reader, the state controller, and the data comparator for providing synchronization between an external clock signal provided by the automatic test equipment and an internal clock signal of the instruction-based P-MBIST circuit.

3. The instruction-based P-MBIST circuit of claim 1, wherein the first address calculator comprises:
a permuter for performing a permutation on the bits of the base address to enforce the carry propagation order according to the control signal;
a first accumulator for adding the first predetermined value or the second predetermined value to an output of the permuter according to the control signal; and
an inverse permuter for performing an inverse permutation on bits of an output of the first accumulator according to the control signal, wherein the permutation and the inverse permutation are exactly inverse to each other.

4. The instruction-based P-MBIST circuit of claim 3, wherein the permuter comprises:
a first rotation device for performing a first rotation operation on the base row address according to a base row rotation signal;
a second rotation device for performing a second rotation operation on the base column address according to a base column rotation signal; and
a switch device for exchanging bit orders of an output of the first rotation device and an output of the second rotation device in response to a switch signal and providing a result of the exchanging to the first accumulator, wherein the control signal comprises the base row rotation signal, the base column rotation signal, and the switch signal;
and the inverse permuter comprises:
an inverse switch device for exchanging bit orders of a row part and a column part of the output of the first accumulator in response to the switch signal;
a first inverse rotation device for performing a first inverse rotation operation on a row part of an output of the inverse switch device according to the base row rotation signal and providing a result of the first inverse rotation operation to the base row loop latch, wherein the first rotation operation and the first inverse rotation operation are opposite in direction; and
a second inverse rotation device for performing a second inverse rotation operation on a column part of the output of the inverse switch device according to the base column rotation signal and providing a result of the second inverse rotation operation to the base column loop latch, wherein the second rotation operation and the second inverse rotation operation are opposite in direction.

5. The instruction-based P-MBIST circuit of claim 4, wherein the state controller generates the base row rotation signal, the base column rotation signal, and the switch signal according to a repeat field of the test instruction.

6. The instruction-based P-MBIST circuit of claim 3, wherein the first accumulator comprises:
a first multiplexer for outputting the first predetermined value or the second predetermined value according to a base step signal, wherein the control signal comprises the base step signal; and
a first adder for adding an output of the first multiplexer to the output of the permuter and providing a result of the adding to the inverse permuter.

7. The instruction-based P-MBIST circuit of claim 1, wherein the base row loop latch comprises:
a base row address register for storing and providing the base row address to the first address calculator; and
a second multiplexer for providing the base row address output by the first address calculator or the base row address output by the base row address register to the base row address register according to a base row hold signal;
and the base column loop latch comprises:
a base column address register for storing and providing the base column address to the first address calculator; and
a third multiplexer for providing the base column address output by the first address calculator or the base column address output by the base column address register to the base column address register according to a base column hold signal;
wherein the control signal comprises the base row hold signal and the base column hold signal.

8. The instruction-based P-MBIST circuit of claim 1, wherein the address generator further comprises:
a second address calculator for adding a third predetermined value or a fourth predetermined value to the base row address or a local row address according to the control signal and providing a result of the adding as the local row address, wherein the second address calculator determines a carry propagation order of bits of the local row address in the adding according to the control signal;
a local row loop latch for storing and providing the local row address output by the second address calculator or the local row address output by the local row loop latch to the second address calculator according to the control signal;
a row multiplexer for outputting the base row address output by the base row loop latch or the local row address output by the local row loop latch as a row address of the memory address according to the control signal;
a third address calculator for adding a fifth predetermined value or a sixth predetermined value to the base column address or a local column address according to the control signal and providing a result of the adding as the local column address, wherein the third address calculator determines a carry propagation order of bits of the local column address in the adding according to the control signal;
a local column loop latch for storing and providing the local column address output by the third address calculator or the local column address output by the local column loop latch to the third address calculator according to the control signal; and
a column multiplexer for outputting the base column address output by the base column loop latch or the local column address output by the local column loop latch as a column address of the memory address according to the control signal.

9. The instruction-based P-MBIST circuit of claim 8, wherein the test instruction comprises an enable field and the enable field comprises at least one of a refresh enable bit, a retention enable bit, a hammer enable bit, and a butterfly enable bit;
when all of the enable bits of the enable field are de-asserted, the state controller performs the memory operation on the embedded memory according to a first test algorithm;
when one of the enable bits of the enable field is asserted, the state controller performs the memory operation on the embedded memory according to a second test algorithm corresponding to the asserted enable bit; the first test algorithm and the second test algorithms corresponding to the enable bits are all different.

10. The instruction-based P-MBIST circuit of claim 9, wherein the first test algorithm performs the memory operation only once on memory cells of the embedded memory corresponding to the base address.

11. The instruction-based P-MBIST circuit of claim 9, wherein the second test algorithm corresponding to the refresh enable bit performs the memory operation on memory cells of the embedded memory corresponding to the base address and then sends a refresh signal to the embedded memory.

12. The instruction-based P-MBIST circuit of claim 9, wherein the second test algorithm corresponding to the retention enable bit performs the memory operation on memory cells of the embedded memory corresponding to the base address and then idles for a predetermined time duration.

13. The instruction-based P-MBIST circuit of claim 9, wherein the second test algorithm corresponding to the hammer enable bit repeats the memory operation for a predetermined number of times on memory cells of the embedded memory corresponding to the base address.

14. The instruction-based P-MBIST circuit of claim 9, wherein the embedded memory comprises a plurality of memory cells and the second test algorithm corresponding to the butterfly enable bit performs the memory operation on the memory cells adjacent to the memory cells corresponding to the base address.

15. The instruction-based P-MBIST circuit of claim 9, wherein the state controller comprises a finite state machine comprising a plurality of states and one of the states is corresponding to the memory operation;
when all of the enable bits of the enable field are de-asserted, the corresponding state performs the memory operation on the embedded memory according to the first test algorithm;
when one of the enable bits of the enable field is asserted, the corresponding state performs the memory operation on the embedded memory according to the second test algorithm corresponding to the asserted enable bit.

16. The instruction-based P-MBIST circuit of claim 8, wherein the second address calculator comprises:
a third rotation device for outputting the base row address provided by the base row loop latch or performing a third rotation operation on the local row address provided by the local row loop latch according to a local row rotation signal;
a second accumulator for adding the third predetermined value or the fourth predetermined value to an output of the third rotation device according to a local row step signal; and
a third inverse rotation device for performing a third inverse rotation operation on an output of the second accumulator according to the local row rotation signal and providing a result of the third inverse rotation operation as the local row address to the local row loop latch, wherein the third rotation operation and the third inverse rotation operation are opposite in direction;
and the third address calculator comprises:
a fourth rotation device for outputting the base column address provided by the base column loop latch or performing a fourth rotation operation on the local column address provided by the local column loop latch according to a local column rotation signal;
a third accumulator for adding the fifth predetermined value or the sixth predetermined value to an output of the fourth rotation device according to a local column step signal; and
a fourth inverse rotation device for performing a fourth inverse rotation operation on an output of the third accumulator according to the local column rotation signal and providing a result of the fourth inverse rotation operation as the local column address to the local column loop latch, wherein the fourth rotation operation and the fourth inverse rotation operation are opposite in direction;
wherein the control signal comprises the local row rotation signal, the local row step signal, the local column rotation signal, and the local column step signal.

17. The instruction-based P-MBIST circuit of claim 16, wherein the state controller generates the local row rotation signal, the local row step signal, the local column rotation signal, and the local column step signal according to an enable field of the test instruction.

18. An address generator for generating a memory address according to a control signal, comprising:
a first address calculator for adding a first predetermined value or a second predetermined value to a base address according to the control signal, wherein the memory address is equal to the base address or is generated according to the base address, the base address comprises a base row address and a base column address, and the first address calculator determines a carry propagation order of bits of the base address in the adding according to the control signal;
a base row loop latch for storing and providing the base row address output by the first address calculator or the base row address output by the base row loop latch to the first address calculator according to the control signal; and
a base column loop latch for storing and providing the base column address output by the first address calculator or the base column address output by the base column loop latch to the first address calculator according to the control signal.

19. The address generator of claim 18, wherein the first address calculator comprises:
a permuter for performing a permutation on the bits of the base address to enforce the carry propagation order according to the control signal;
a first accumulator for adding the first predetermined value or the second predetermined value to an output of the permuter according to the control signal; and
an inverse permuter for performing an inverse permutation on bits of an output of the first accumulator according to the control signal, wherein the permutation and the inverse permutation are exactly inverse to each other.

20. The address generator of claim 19, wherein the permuter comprises:
a first rotation device for performing a first rotation operation on the base row address according to a base row rotation signal;
a second rotation device for performing a second rotation operation on the base column address according to a base column rotation signal; and
a switch device for exchanging bit orders of an output of the first rotation device and an output of the second rotation device in response to a switch signal and providing a result of the exchanging to the first accumulator, wherein the control signal comprises the base row rotation signal, the base column rotation signal, and the switch signal;
and the inverse permuter comprises:
an inverse switch device for exchanging bit orders of a row part and a column part of the output of the first accumulator in response to the switch signal;
a first inverse rotation device for performing a first inverse rotation operation on a row part of an output of the inverse switch device according to the base row rotation signal and providing a result of the first inverse rotation operation to the base row loop latch, wherein the first rotation operation and the first inverse rotation operation are opposite in direction; and
a second inverse rotation device for performing a second inverse rotation operation on a column part of the output of the inverse switch device according to the base column rotation signal and providing a result of the second inverse rotation operation to the base column loop latch, wherein the second rotation operation and the second inverse rotation operation are opposite in direction.

21. The address generator of claim 19, wherein the first accumulator comprises:
a first multiplexer for outputting the first predetermined value or the second predetermined value according to a base step signal, wherein the control signal comprises the base step signal; and
a first adder for adding an output of the first multiplexer to the output of the permuter and providing a result of the adding to the inverse permuter.

22. The address generator of claim 18, wherein the base row loop latch comprises:
a base row address register for storing and providing the base row address to the first address calculator; and
a second multiplexer for providing the base row address output by the first address calculator or the base row address output by the base row address register to the base row address register according to a base row hold signal;
and the base column loop latch comprises:
a base column address register for storing and providing the base column address to the first address calculator; and
a third multiplexer for providing the base column address output by the first address calculator or the base column address output by the base column address register to the base column address register according to a base column hold signal;
wherein the control signal comprises the base row hold signal and the base column hold signal.

23. The address generator of claim 18, further comprising:
a second address calculator for adding a third predetermined value or a fourth predetermined value to the base row address or a local row address according to the control signal and providing a result of the adding as the local row address, wherein the second address calculator determines a carry propagation order of bits of the local row address in the adding according to the control signal;
a local row loop latch for storing and providing the local row address output by the second address calculator or the local row address output by the local row loop latch to the second address calculator according to the control signal;
a row multiplexer for outputting the base row address output by the base row loop latch or the local row address output by the local row loop latch as a row address of the memory address according to the control signal;
a third address calculator for adding a fifth predetermined value or a sixth predetermined value to the base column address or a local column address according to the control signal and providing a result of the adding as the local column address, wherein the third address calculator determines a carry propagation order of bits of the local column address in the adding according to the control signal;
a local column loop latch for storing and providing the local column address output by the third address calculator or the local column address output by the local column loop latch to the third address calculator according to the control signal; and
a column multiplexer for outputting the base column address output by the base column loop latch or the local column address output by the local column loop latch as a column address of the memory address according to the control signal.

24. The address generator of claim 23, wherein the second address calculator comprises:
a third rotation device for outputting the base row address provided by the base row loop latch or performing a third rotation operation on the local row address provided by the local row loop latch according to a local row rotation signal;
a second accumulator for adding the third predetermined value or the fourth predetermined value to an output of the third rotation device according to a local row step signal; and
a third inverse rotation device for performing a third inverse rotation operation on an output of the second accumulator according to the local row rotation signal and providing a result of the third inverse rotation operation as the local row address to the local row loop latch, wherein the third rotation operation and the third inverse rotation operation are opposite in direction;
and the third address calculator comprises:
a fourth rotation device for outputting the base column address provided by the base column loop latch or performing a fourth rotation operation on the local column address provided by the local column loop latch according to a local column rotation signal;
a third accumulator for adding the fifth predetermined value or the sixth predetermined value to an output of the fourth rotation device according to a local column step signal; and
a fourth inverse rotation device for performing a fourth inverse rotation operation on an output of the third accumulator according to the local column rotation signal and providing a result of the fourth inverse rotation operation as the local column address to the local column loop latch, wherein the fourth rotation operation and the fourth inverse rotation operation are opposite in direction;
wherein the control signal comprises the local row rotation signal, the local row step signal, the local column rotation signal, and the local column step signal.
